(19) United States
(12) Patent Application Publication
(10) Pub. No.: US 2014/0264536 A1
(43) Pub. Date: Sep. 18, 2014

(54) NONVOLATILE SEMICONDUCTOR STORAGE DEVICE AND METHOD OF MANUFACTURING THE SAME

(71) Applicant: KABUSHIKI KAISHA TOSHIBA, MINATO-KU (JP)

(72) Inventors: Hideto TAKEKIDA, Nagoya (JP); Akimichi Goyo, Yokohama (JP)

(73) Assignee: KABUSHIKI KAISHA TOSHIBA, MINATO-KU (JP)

(21) Appl. No.: 13/975,687

(22) Filed: Aug. 26, 2013

(30) Foreign Application Priority Data
Mar. 12, 2013 (JP) 2013-049070

(51) Int. Cl. H01L 27/115; H01L 21/28

(52) U.S. Cl. CPC H01L 27/11524; H01L 21/28273
USPC 257/316; 438/593

(57) ABSTRACT

A nonvolatile semiconductor storage device including memory-cell transistors located in a memory-cell region, each of the transistors including a gate insulating film formed on a semiconductor substrate and a memory-cell gate electrode including a first semiconductor film, an insulating film, and a conductive film; word lines each interconnecting the conductive film of the transistors aligned in a first direction and each including a hook-up portion located in a hook-up region located outside the memory-cell region; and an interlayer insulating film disposed on the upper surface of the memory-cell gate electrodes so as to form a gap between the memory-cell gate electrodes; wherein a second semiconductor film and a first insulating film are disposed in the hook-up region, wherein the interlayer insulating film covers an upper surface of the first insulating film and an upper surface of the plurality of word lines in the hook-up portion.

### CROSS-REFERENCE TO RELATED APPLICATION(S)

This application is based upon and claims the benefit of priority from Japanese Patent Application No. 2013-049070, filed on, Mar. 12, 2013 the entire contents of which are incorporated herein by reference.

### FIELD

Embodiments disclosed herein generally relate to a nonvolatile semiconductor storage device and a method of manufacturing the same.

### BACKGROUND

According to shrink of memory cells in nonvolatile semiconductor devices such as NAND flash memory, a few development points are coming. One of these, a parasitic capacitance is large because of gate electrodes becoming closer together. Then, gaps containing air or vacuum gaps, unfilled with insulating film, are provided between gate electrodes of memory cells. In such insulation scheme, it is preferable to seal the gaps in order to prevent entering of chemical liquids, resist, film-forming gases or other materials used in the manufacturing process flow into the gaps.

Another of these, metal contamination occurs when a device contains a stack of polycrystalline silicon film and metal film. When such stack is etched during gate patterning, the metal particles attach to the surface of the semiconductor substrate or its surrounding structures.

The parasitic capacitance or the metal contamination may lead to degradation of properties of the nonvolatile semiconductor storage device.

### BRIEF DESCRIPTION OF THE DRAWINGS

FIG. 1 is one schematic example of a block diagram of a NAND flash memory cell region according to a first embodiment.

FIG. 2 is one schematic example of an electrical configuration of a memory cell region in part.

FIG. 3 is one schematic example of a plan view partially illustrating a layout of the memory cell region and a hook-up region of word lines.

FIG. 4 is one schematic example of a cross sectional view illustrating a memory cell unit configuration.

FIG. 5A is one schematic example of a vertical cross-sectional view taken along line 5A-5A of FIG. 3.

FIG. 5B is a one schematic example of a vertical cross-sectional view taken along line 5B-5B of FIG. 3.

FIG. 6A is one schematic example of a cross-sectional view taken along line 6A-6A of FIG. 3.

FIG. 6B is a one schematic example of a cross-sectional view taken along line 6B-6B of FIG. 3.

FIGS. 7A to 11B each illustrate one phase of the manufacturing process flow; where FIGS. 7A, 8A, 9A, 10A, and 11A each illustrate one schematic example of a cross-sectional view taken along line 5A-5A of FIG. 3; and FIGS. 7B, 8B, 9B, 10B, and 11B, each illustrate one schematic example of a cross-sectional view taken along line 5B-5B of FIG. 3.

FIG. 12A illustrates a second embodiment and is one example of cross section taken along line 5A-5A of FIG. 3.

FIG. 12B is one example of a plan view of a peripheral circuit transistor.

FIG. 12C is one example of a cross sectional view taken along line 12C-12C of FIG. 12B.

FIGS. 13A to 17B each illustrate one phase of the manufacturing process flow; where FIGS. 13A, 14A, 15A, 16A, and 17A, each illustrate one schematic example of a cross sectional view taken along line 5A-5A of FIG. 3; and FIGS. 13B, 14B, 15B, 16B, and 17B each illustrate one example of a cross sectional view of a peripheral circuit transistor.

FIG. 18A illustrates a third embodiment and is one example of a plan view of a peripheral circuit transistor.

FIG. 18B is one example of a cross sectional view taken along line 18B-18B of FIG. 18A.

FIG. 19A illustrates a fourth embodiment and is one example of a cross sectional view taken along line 5A-5A of FIG. 3.

FIG. 19B is one example of a cross sectional view of a peripheral circuit transistor.

FIGS. 20A to 24B each illustrate one phase of the manufacturing process flow; where FIGS. 20A, 21A, 22A, 23A, and 24A, each illustrate one schematic example of a cross-sectional view taken along line 5A-5A of FIG. 3; and FIGS. 20B, 21B, 22B, 23B, and 24B, each illustrate one example of a cross sectional view of a peripheral circuit transistor.

### DESCRIPTION

In one embodiment, a nonvolatile semiconductor storage device is disclosed. The device includes a semiconductor substrate; a plurality of memory-cell transistors located in a memory-cell region, each of the memory-cell transistors including a gate insulating film formed on the semiconductor substrate and a memory-cell gate electrode including a first semiconductor film, an insulating film, and a conductive film; a plurality of word lines each interconnecting the conductive film of the memory-cell transistors aligned in a first direction and each including a hook-up portion located in a hook-up region located outside the memory-cell region; and an interlayer insulating film disposed on the upper surface of the memory-cell gate electrodes so as to form a gap between the memory-cell gate electrodes; wherein a second semiconductor film and a first insulating film are disposed in the hook-up region, the second semiconductor film and the first semiconductor film being made of the same material, and the insulating film and the first insulating film being made of the same material, and wherein the interlayer insulating film covers an upper surface of the first insulating film and an upper surface of the plurality of word lines in the hook-up portion.

### EMBODIMENTS

Embodiments are described hereinafter through a NAND flash memory application with references to the accompanying drawings. The drawings are not drawn to scale and thus, do not reflect the actual measurements of the features such as the correlation of thickness to planar dimensions and the relative thickness of different layers. Further, directional terms such as up, upper, upward, down, lower, downward, left, leftward, right, and rightward are used in a relative context with an assumption that the worked surface, on which circuitry is formed, of the later described semiconductor substrate faces up. Thus, the directional terms do not necessarily correspond to the directions based on gravitational acceleration.

### First Embodiment

A description is given hereinafter on a first embodiment with reference to FIGS. 1 to 11.

FIG. 1 is one example of a schematic representation of a block configuration of NAND flash memory device 1. It can be seen from FIG. 1 that the chip layout of NAND flash memory device 1 primarily comprises a plurality of memory cell regions M and peripheral circuit region P provided around memory cell regions M. Each of the memory cell regions M contain multiplicity of blocks B which contain multiplicity of memory-cell transistors arranged in a matrix. Peripheral circuit region P comprises components such as a row decoder, a sense amplifier, a logical circuit, a control circuit, and a power-supply capacitor that are provided for each block. The row decoder boosts the voltage of the word lines. The sense amplifier is responsible for current detection. The logical circuit and the control circuit process incoming signals.

Memory-cell transistor Trm is capable of nonvolatile storage of data by controlling the state of charge storage in the floating gate electrode. For instance, when the threshold voltage of the floating gate electrode, being injected with electrons through the channel, is high, such state is associated with data “0”. When the threshold voltage of the floating gate electrode, having released electrons into the channel, is low, such state is associated with data “1”. Memory-cell transistor Trm stores either of the binary data. Multi-value storage scheme that stores quaternary or octary values, etc. may be employed by refining the control of threshold distribution. The peripheral circuitry provided in peripheral circuit P controls programming, erasing, and reading of data to/from memory-cell transistor Trm.

FIG. 2 is one example of a partial equivalent circuit representation of a single block within an array of memory-cell transistors Trm located in memory cell region M.

The memory cell array of NAND flash memory device includes k number of columns of cell groups also referred to as NAND cell units SU. It is to be noted that “k” is a positive integer which is equal to or greater than 2. NAND cell unit SU comprises a multiplicity of series connected memory-cell transistors Trm, such as 32 in number, situated between a couple of select transistors Trs1 and Trs2 that are located at Y-direction ends of NAND cell unit SU. The neighboring memory-cell transistors Trm within NAND cell unit SU share their source/drain regions.

The X-direction aligned memory-cell transistors Trm shown in FIG. 2 are interconnected by a common word line extending in the X direction which is the width direction of the gate. Each of the rows of memory-cell transistors Trm interconnected by word lines WL0 to WL31 represents a page which is numbered from 0 to 31 and identified as PAGE1 to PAGE31 in FIG. 2 so as to correspond to the word lines. The X-direction aligned select transistors Trs1 are interconnected by common select gate line SGL1 extending in the X direction as viewed in FIG. 2 and likewise, the X-direction aligned select transistors Trs2 are interconnected by common select gate line SGLD/SGLS also extending in the X direction. The drain of each select transistor Trs1 is coupled to bit line BL by way of bit line contact CB. Bit line BL extends in the Y direction which is the length direction of the gate and the direction orthogonal to the X direction as viewed in FIG. 2. The source of each select transistor Trs2 is coupled to source line SL extending in the X-direction as viewed in FIG. 2.

FIG. 3 is one example of a plan view partially illustrating the layout of memory cell region M and hook-up region T of word lines WL. Hook-up region T is a region where word lines extracted from memory cell region M are connected to the upper interconnect layer through a contact. Hook-up region T is typically located beyond the end portion of the repeated line and space pattern of memory cell region M. In the example shown in FIG. 3, hook-up region T is located in the X-directional right side of memory cell region M. FIG. 3 shows the state in which the gate electrodes have been isolated but are yet to be covered by overlying structures such as an interlayer insulating film. Referring to FIG. 3, multiplicity of element isolation regions Sb run in the Y direction of memory cell region M of silicon substrate 2, or more generally, a semiconductor substrate. Element isolation regions Sb are separated from one another in the X direction as viewed in FIG. 2 to isolate element regions Sa, running in the Y-direction, by a predetermined space interval in the X direction. The isolation employs a shallow trench isolation scheme known as STI. A plurality of word lines WL of memory-cell transistors Trm extend in the X direction as viewed in FIG. 3 which is a directional orthogonal to element region 4. Word lines are spaced from one another in the Y direction as viewed in FIG. 3.

A pair of select gate lines SGLD associated with the pair of select transistors Trs1, hereinafter simply referred to as Trs, extend in the X direction as viewed in FIG. 3. In each of element regions Sa located between the pair of opposing select gate lines SGLD, bit line contact CB is formed. Above element region Sa intersecting with word line WL, gate electrode MG of memory-cell transistor Trm is formed. Similarly, above element region 4 intersecting with select gate line SGLD, select gate electrode SG of select transistor Trs is formed.

In hook-up region T, hook-up portion WLa of word line WL is formed so as to extend in the X direction as viewed in FIG. 3. The right ends of hook-up portions WLa of the group of word lines WL located in the upper portion of FIG. 3 are bent in the Y direction and each terminates into pad portion WLb. Though not shown, pad portion WLb of the group of word lines WL in the lower portion of FIG. 3 is formed in the hook-up region of the word lines provided on the left side of FIG. 3. In the first embodiment, pad portions WLb of the group of word lines WL are formed alternately in hook-up region T of word lines WL located in the right side of FIG. 3 and in the hook-up region of word line WL located in the left side of FIG. 3.

FIG. 4 is one example of a schematic cross sectional structure taken along cell unit SU of FIG. 2 illustrating memory cell region M. Referring to FIG. 4, a gate insulating film not shown is formed above the upper surface of silicon substrate 2 and gate electrodes MG of memory-cell transistors Trm and gate electrodes SGS and SGD of select transistors Trs1 and Trs2 are formed above the gate insulating film. Memory-cell transistor Trm comprises, gate insulating film, gate electrode MG and source/drain region 2a. As described earlier, a plurality of Y-directionally adjacent memory-cell transistors Trm form NAND cell unit. A pair of select transistors Trs1 is formed adjacent to memory-cell transistor Trm at one end of cell unit SU and a pair of select transistors Trs2 is formed adjacent to the other end of cell unit SU.

As described earlier, gate electrode MG is formed above a gate insulating film and is configured by a floating gate electrode FG, an interelectrode insulating film, and control gate electrode CG stacked in the listed sequence. Control gate electrodes CG serves as word line WL that interconnect gate electrodes MG of adjacent cell units SU. In the surface layer of silicon substrate 2 located between gate electrodes MG and between gate electrode SG and MG source/drain region 2a is provided. Gate electrode SG is also identified as SGS and SGD in the drawings. In the surface layer of silicon substrate 2 located between gate electrodes SG, more specifically, between gate electrodes SGS and between gate electrodes SGD, source/drain region 2b is provided. Source/drain regions 2a and 2b may be formed by introducing impurities into the surface layer of silicon substrate 2. Source/drain region 2b employs an LDD (Lightly Doped Drain) structure which is formed by a combination of a region doped with low-concentration impurities and a region doped with high-concentration impurities.

Though not discernable in the simplified illustration in FIG. 4, gate electrodes SGS and SGD of select transistors Trs1 and Trs2 are substantially identical in film structure to gate electrode MG of memory-cell transistor Trm. In gate electrodes SGS and SGD, an opening is formed through the interelectrode insulating film to short the floating gate electrode and the select gate electrode.

The above described gate electrodes MG, SG (SGS, SGD) are formed with an interlayer insulating film so as to be buried in the interlayer insulating film. Gate electrodes MG are insulated from one another by a so-called air gap structure exemplified in FIG. 5A in which the gaps between gate electrodes MG are not filled with an insulating film to thereby define air gap AG. Gate electrode MG and SG (SGS, SGD) are insulated in the same manner. The gaps between gate electrodes SGS and between SGD are insulated by a gap fill insulating film.

Between gate electrodes SGS, source contact CS is provided that contacts source region 2b of silicon substrate 2. Source contact CS is connected to source line SL shown in FIG. 2A. Source contact CS is formed so as to extend across source regions 2b of X-directionally adjacent transistors Trs1 that are isolated by element isolation region Sb. Between gate electrodes SGD, bit line contact CB is provided that contacts drain region 2b of silicon substrate 2. As referred to earlier, bit line contact CB is also shown in FIGS. 2 and 3.

Source line SL being located above and electrically connected to source contact CS is buried in the interlayer insulating film. Source line SL is formed substantially in the same direction as word line WL located in the lower layer. Referring back to FIG. 2, bit line BL is formed along the Y direction in which element isolation region Sa and NAND cell unit SU extends so as to be in orthogonal to source line SL.

One example of the structures of the first embodiment will be described with reference to FIGS. 5A and 5B. FIGS. 5A and 5B are examples of cross sectional views taken along lines 5A-5A and 5B-5B of FIG. 3. As shown in FIG. 4, isolation between gate electrodes MG is achieved in the first embodiment by an unfilled gap, also referred to and shown as air gap AG, instead of filling of an insulation film for better insulativity. FIG. 5A is a cross sectional view illustrating one phase of the manufacturing process flow in which air gap AG is formed after isolating gate electrodes MG of memory-cell transistors Trm. This is followed by formation of gate electrodes SG of select gate transistors Trs and gate electrodes PG of peripheral circuit transistor Trp.

As can be seen in FIG. 5A, gate electrode MG is formed above silicon substrate 2 via gate insulating film 3. Gate electrode MG comprises polycrystalline silicon film 4 also referred to as a first/second semiconductor film, interelectrode insulating film 5, polycrystalline silicon film 6 also referred to as a conductive film, and tungsten (W) film 7 also referred to as a metal film stacked in the listed sequence. Silicon nitride film 8 serving as a hard mask is further formed above gate electrode MG.

Gate insulating film 3 may comprise a silicon oxide film. Interelectrode insulating film 5 may comprise an ONO (oxide-nitride-oxide) film or NONON (nitride-oxide-nitride-oxide-nitride) film or high dielectric constant insulating film. Tungsten film 7, located above polycrystalline silicon film 6, may be formed with an intervention of a barrier metal film such as tungsten nitride (WN) film. Polycrystalline silicon film 4 serves as floating gate electrode FG, whereas polycrystalline silicon film 6 and tungsten film 7 serves locally as control gate electrode CG and globally as word line WL.

Gate electrode MG is spaced from the adjacent gate electrode MG by a MG-MG distance. Gate electrode MG located adjacent to select gate electrode SG is spaced from select gate electrode SG by a distance slightly greater than the MG-MG distance. Gate insulating film 3 located between each of gate electrodes MG may be removed. Silicon oxide film 9 is lined along the upper surface and sidewalls of each gate electrode MG as well as along the surface of silicon substrate 2 where source/drain region 2a is formed.

Silicon oxide film 10 for capping the unfilled gap is formed over silicon oxide film 9 in order to form the air gap. Silicon oxide film 10 is formed under conditions providing poor gap fill capability. Formation of silicon oxide film 10 starts as a thin layer that lines the upper surface and sidewalls of gate electrode MG as well as the surface of silicon substrate 2. The formation progresses so as to cap the upper portion of the gaps between gate electrodes MG and between gate electrode MG and the adjacent gate electrode SG without filling the gaps to obtain air gaps AG. Interlayer insulating film 11 comprising a silicon oxide film for example is further lined along the upper surface of silicon oxide film 10 to allow air gaps AG to be completely sealed.

As can be seen in the right side portion of FIG. 5A where select gate electrodes SG of select transistors Trs are to be formed, gate isolation is yet to be carried out and thus, the adjacent gate electrodes SG are not isolated from one another. Opening 5a is formed through interelectrode insulating film 5 at locations where the adjacent gate electrodes are to be formed. Opening 5a extends partially into polycrystalline silicon film to define a recess in polycrystalline silicon film 4. Polycrystalline silicon film 6 is formed into the recess through opening 5a, thereby electrically shorting polycrystalline silicon films 4 and 6.

FIG. 5B illustrates the cross section of pad portion WLb of word line WL located in hook-up region T. As shown in FIG. 5B, gate insulating film 3, polycrystalline silicon film 4, and interelectrode insulating film 5 are stacked in the listed sequence above silicon substrate 2. Pad portion WLb comprises polycrystalline silicon film 6, tungsten film 7, and silicon nitride film 8, which are dimensioned at a predetermined width, stacked in the listed sequence above interelectrode insulating film 5. Along the upper surface and the sidewalls of pad portion WLb as well as along the upper surface of interelectrode insulating film 5 exposed between pad portions WLb, silicon oxide film 9 is formed.

Silicon oxide film 9 is further covered by silicon oxide film 10 which encapsulates or encloses the air gaps by capping them. Because the spacing between two adjacent pad portions WLb are greater than the spacing between two adjacent word lines WL, the space between pad portions WLb are covered with silicon oxide film 10. Interlayer insulating film 11 is further formed along the upper surface of silicon oxide film 10.

The above described pad portion WLb is formed in the hatched portion, represented as region K in FIG. 3, of hook-up region T. Region K is structured by silicon substrate 2 which is covered by gate insulating film 3 and polycrystalline silicon film 4 in the listed sequence as was the case for pad portion WLb. Still referring to FIG. 3, the portion of region K′ located between select gate electrode lines SGLD and taken along line 5A-5A is also structured by silicon substrate 2 which is covered by gate insulating film 3 and polycrystalline silicon film 4 in the listed sequence and is processed into the structure illustrated in FIG. 5A.

Next, referring to FIGS. 6A and 6B, one example of a cross sectional shape of the terminating end of word line WL located in hook-up region T will be described with reference to FIGS. 6A and 6B. FIG. 6A is one example of a cross sectional view taken along line 6A-6A of FIG. 3, and FIG. 6B is one example of a cross sectional view taken along line 6B-6B of FIG. 3.

More specifically, FIG. 6A is one example of a cross sectional view illustrating the boundary region between region Sw and the above described region K. Region Sw is a region located between hook-up portion WLa where air gap AG is formed. FIG. 6B is one example of a cross sectional view illustrating the boundary region between hook-up portion WLa and region K.

As shown in FIG. 6A, region Sw is structured by air gap AG comprising an unfilled gap provided above silicon oxide film 9 formed above silicon substrate 2. Air gap AG is capped by silicon oxide film 10 which is further covered by interlayer insulating film 11. In the boundary region between region Sw and region K, polycrystalline silicon film 4 partially remains above gate insulating film 3. In region K, polycrystalline silicon film 4 and interelectrode insulating film 5 fully remain above gate insulating film 3. Silicon oxide film 9 is lined entirely across region Sw and region K. In one example, edge of polycrystalline silicon film 4 exposed by air gap AG may form a curved surface. As shown in FIG. 6A, the boundary between gate insulating film 3 and silicon oxide film 9 may be located on the extension of the curved surface. Silicon oxide film 9 extends upward along the curved surface of polycrystalline silicon film 4 from the boundary and further along the upper surface of polycrystalline silicon film 4. The thickness of gate insulating film 3 and silicon oxide film 9 may vary. Still referring to FIG. 6A, silicon oxide film 10 and interlayer insulating film 11 gradually descend to establish intimate contact with silicon oxide film 9 formed above the upper surface of polycrystalline silicon film 4 located near the boundary between region Sw and region K so as to seal off air gap AG.

Referring now to FIG. 6B, gate insulating film 3, polycrystalline silicon film 4, and interelectrode insulating film 5 are stacked in the listed sequence above silicon substrate 2 located in both hook-up portion WLa and region K. The stack of polycrystalline silicon film 6, tungsten film 7, and silicon nitride film 8 constituting hook-up portion WLa extend to the boundary region between hook-up portion WLa and region K. Silicon oxide film 9 is formed along the upper surface and sidewalls of hook-up portion WLa and further along the surface of interelectrode insulating film 5 located in region K. Similar to the structure illustrated in FIG. 6A, silicon oxide film 10 and interlayer insulating film 11 formed along hook-up portion WLa via silicon oxide film 9 gradually descend in the region near the boundary between the terminating end of hook-up portion WLa and region K.

The above described structure allows air gap AG formed between word lines WL and between hook-up portions WLa to be sealed off by silicon oxide film 10 near the boundary region with region K. In region K, polycrystalline silicon film 4, interelectrode insulating film 5, and silicon oxide film 9 remain above gate insulating film 3. Thus, in region K, silicon oxide film 10 is formed so as to cover height D corresponding to the height of hook-up portion WLa of word line WL. Hence, in the first embodiment, silicon oxide film 10 can be formed with improved step coverage in region K as compared to a structure in which silicon oxide film 9, interelectrode insulating film 5, and polycrystalline silicon film 4 are removed in region K, which results in height Dx greater than the height D.

Next, a description will be given on one example of a manufacturing process flow of the above described structure with reference to FIGS. 7A to 11B as well. FIGS. 7A, 8A, 9A, 10A, and 11A are examples of one phase of the manufacturing process flow of the structure illustrated in FIG. 5A, whereas FIGS. 7B, 8B, 9B, 10B, and 11B are examples of one phase of the manufacturing process flow of the structure illustrated in FIG. 5B.

In FIGS. 7A and 7B, gate insulating film 3, polycrystalline silicon film 4, interelectrode insulating film 5, polycrystalline silicon film 6, tungsten film 7, and silicon nitride film 8 are stacked in the listed sequence above the upper surface of silicon substrate 2. Polycrystalline silicon film 4 is one example of a first/second semiconductor film and polycrystalline silicon film 6 is one example of a conductive film. Tungsten film 7 is one example of a metal film. Polycrystalline silicon film 4 is also one example of floating gate electrode FG. Combination of polycrystalline silicon film 6 and tungsten film 7 is one example of control gate electrode CG which also serves as word line WL and takes a so-called poly metal structure.

Formation of tungsten film 7 preferably follows formation of barrier metal film such as tungsten nitride film above polycrystalline silicon film 6. In the portions for forming gate electrodes SG in the structure of FIG. 7A, opening 5a is formed through interelectrode insulating film 5 in advance to allow polycrystalline silicon film 4 and polycrystalline silicon film 6 to establish electrical contact through opening 5a.

Though not shown, element isolation trenches are formed into the surface of silicon substrate 2 as described earlier and are filled with element isolation insulating film to form element isolation regions Sb. Element isolation regions Sb isolate silicon substrate 2 into element regions Sa. Element isolation regions Sb isolate polycrystalline silicon film 4 in the X direction as viewed in FIG. 3 to obtain isolated and independent floating gate electrode FG above element regions Sa.

Referring now to FIGS. 8A and 8B, gate patterning is carried out. In the first embodiment, isolation between gate electrodes MG is carried out prior to isolation of gate electrode SG. The gate patterning beings with anisotropic etching of silicon nitride film 8, tungsten film 7, and polycrystalline silicon film 6 using RIE (reactive ion etching). As shown in FIG. 8B, hook-up portion WLa of the select gate line and pad portion WLb may be also processed at the same time. The gate patterning exposes the upper surface of interelectrode insulating film 5 located between gate electrodes MG, between gate electrode MG and SG and between pad portions WLb. The gate patterning further exposes the sidewalls of tungsten film 7 of gate electrode MG, gate electrode SG, and pad portion WLb, respectively.

Because the gate patterning involves etching of tungsten film 7, etch residues of tungsten (metal particles) may scatter on to peripheral structures. In order to prevent such tungsten etch residues from coming in direct contact with the surface of silicon substrate 2 or gate insulating film 3, RIE is temporarily stopped using interelectrode insulating film 5 as a stopper.

Referring now to FIGS. 9A and 9B, silicon oxide film 12, serving as a cover insulating film, is formed over the upper surface of the resulting structure. A cleaning process or the like for removing the etch residue may be carried out prior to this step. Silicon oxide film 12 is formed using plasma under conditions providing poor step coverage. As a result, silicon oxide film 12 is difficult to form on the upper surface of interelectrode insulating film 5, exposed in the narrow gap between gate electrode MG by the etching, while being formed along the upper surface and sidewalls of silicon nitride film 8 and the sidewalls of tungsten film 7. Thus, silicon oxide film 12 covers the surfaces of tungsten film 7 exposed by the gate patterning while leaving clearance between the memory-cell transistors Trm. Even if sidewalls of tungsten film 7 are only partially covered by silicon oxide film 12, etch residue contamination can be prevented more effectively as compared to a complete absence of silicon oxide film 12. Depending upon the applied conditions, silicon oxide film 12 being formed in an isolated manner as shown in FIG. 9A may be formed so as to contact silicon oxide films 12 between each of the adjacent gate electrodes MG. In such case, the length of contacting portion of silicon oxide films 12 is configured to be less than the length or the height of silicon oxide film 12 formed on the upper surfaces of gate electrodes MG. Such configuration allows etching between gate electrodes MG without etching the upper surfaces of gate electrodes MG.

Referring to FIG. 9B, pad portions WLb are isolated by a greater spacing as compared to the spacing between gate electrodes MG. Thus, silicon oxide film 12 is formed continuously along the upper surface and sidewalls of pad portions WLb and interelectrode insulating film 5 without any disconnecting gaps between pad portions WLb. In case interelectrode insulating film 5 is removed by the aforementioned etching, silicon oxide film 12 is formed along the underlying polycrystalline silicon film 4.

Referring now to FIG. 10A, gate patterning is resumed using silicon oxide film 12 as a mask. In case the clearance between gate electrodes MG are closed by silicon oxide film 12, silicon oxide film 12 may be etched by RIE so as to reestablish the clearance between gate electrodes MG. Then, RIE progresses through the clearance to remove interelectrode insulating film 5 and polycrystalline silicon film 4 located between gate electrode MG to obtain the gate structure of gate electrode MG. Gate insulating film 3 located between gate electrodes MG and between gate electrode MG and gate electrode SG may also be removed at this timing.

Referring to FIG. 10B, in region K, the layers below interelectrode insulating film 5 are not etched because silicon oxide film 12 is formed on the pad portions WLb and between the pad portions WLb. Silicon oxide film 12 is thereafter removed. As a result, polycrystalline silicon film 4 remains in pad portion WLb of region K.

The anisotropic etching by RIE may slightly etch silicon oxide film 12. However, the etching progresses under conditions to selectively etch polycrystalline silicon film 4. Thus, silicon oxide film 12 is not etched in large amount. As a result, the exposed portion of tungsten film 7 is protected by silicon oxide film 12.

Using silicon oxide film 12 as a mask in the etching provides the following advantages. The surfaces of tungsten film are covered by silicon oxide film 12 when etching polycrystalline silicon film 4. This prevents the scattering of tungsten on to the exposed gate insulating film 3 and therefore prevents contamination of gate insulating film 3. This is advantageous in eliminating one of the factors that degrade the properties of memory-cell transistor Trm.

Then, as shown in FIGS. 11A and 11B, silicon oxide film 9 serving as a protective film for protecting the sidewalls of gate electrode MG is formed by methodologies such as HTO (High Temperature Oxidation) and CVD (Chemical Vapor Deposition). In the structure illustrated in FIG. 11A, silicon oxide film 9 is formed along the sidewalls and upper surface of gate electrode MG as well as along the surface of semiconductor substrate 2. In the structure illustrated in FIG. 11B, silicon oxide film 9 is further formed along the upper surface and sidewalls of pad portions WLb as well as the exposed surface of interelectrode insulating film 5.

Next, as shown in FIG. 5A, silicon oxide film 10 for the air gaps is formed under conditions providing poor step coverage. Thus, silicon oxide film 10 is not formed inside the narrow gaps between gate electrodes MG but instead is formed to extend across the upper surfaces of gate electrodes MG. As a result, unfilled gaps referred to and shown as air gaps AG are obtained in which silicon oxide film 10 does not fill the gap between gate electrodes MG.

As shown in FIG. 5B, air gaps are not formed in region K in which pad portions WLb are formed. Instead, silicon oxide film 10 is formed along the upper surface and sidewalls of pad portion WLb as well as along silicon oxide film 9. As shown in FIGS. 6A and 6B, silicon oxide film 10 is not formed in region Sw located between hook-up portions WLa since the Y directional spacing between hook-up portions WLa as viewed in FIG. 3 is narrow. As a result, silicon oxide film 10 is formed so as to cover hook-up portions WLa of word lines WL to form air gaps AG in regions Sw located between hook-up portions WLa.

Though not shown, structures illustrated in FIGS. 5A and 5B are further patterned to form the gate structures of gate electrodes SG. Polycrystalline silicon film 4 and the overlying stack of films are removed to form bit line contact CB or source line contact SB typically between the adjacent select gate electrodes SG.

Referring back to FIG. 3, polycrystalline silicon film 4 and the overlying stack of films are removed when forming the gate structures of gate electrodes SG in region K′ located between a couple of hook-up portions SGLDa of select gate lines SGLD in hook-up region T.

The first embodiment provides the following advantages.

Gate patterning is temporarily stopped once polycrystalline silicon film 6 has been etched. Etching is performed after silicon oxide film 12 is formed so as to cover the surfaces of tungsten film 7. Further, though control gate electrode CG employs a poly-metal structure in which tungsten film 7 is stacked above polycrystalline silicon film 6, the first embodiment prevents scattering of tungsten etch residues from the worked surfaces of tungsten film 7 to suppress contamination of gate insulating film 3 or silicon substrate 2 caused by attachment of tungsten, or any other metal films used instead of tungsten, during gate patterning.

Further, because silicon oxide film 12 is formed under conditions providing poor step coverage, silicon oxide film 12 is formed along the upper surface of interelectrode insulating film 5 located between pad portions WLb in hook-up region T, since spacing between pad portions WLb are relatively wide. Thus, in region K within hook-up region T, interelectrode insulating film 5 and polycrystalline silicon film 4 remain in the gate patterning. This allows the clearance to be covered by silicon oxide film 10 at the terminating end of hook-up portion WLa to be reduced to height D which is much less than height Dx when interelectrode insulating film 5 and polycrystalline silicon film 4 are removed. Hence, in the subsequent formation of silicon oxide film 10 for forming the air gaps can be formed with improved step coverage because air gaps AG can be more tightly sealed. As a result, it is possible to prevent intrusion of chemical liquids, resist, film forming gas, or the like into air gap AG or unfilled gap.

It may seem that hook-up portions WLa may short with one another in hook-up region T since polycrystalline silicon film 4, interelectrode insulating film 5, and silicon oxide film 9 are formed continuously in hook-up portions WLa and the portions between pad portions WLb. However, polycrystalline silicon film 6 and tungsten (W) film 7 of hook-up portion WLa are respectively isolated from polycrystalline silicon film 4 by interelectrode insulating film 5. As a result, hook-up portions WLa are electrically isolated and each of word lines WL is used as wires.

As set forth above, the first embodiment prevents property degradation of nonvolatile semiconductor storage device.

### Second Embodiment

FIGS. 12A to 17B illustrate a second embodiment. The second embodiment addresses tungsten contamination encountered during gate patterning of gate electrode SG of select transistor Trs and gate electrode PG of peripheral circuit transistor Trp. The following description is primarily directed to the differences from the first embodiment. The second embodiment will be described based on the structure exemplified in the first embodiment in which gate electrodes MG of memory-cell transistors Trm are formed. The second embodiment, however, is not limited to application to structures including unfilled gaps as was the case in the first embodiment.

FIG. 12A is one example of a cross sectional view taken along line 5A-5A of FIG. 3. FIG. 12B is one example of a plan view of a peripheral circuit transistor. FIG. 12C is one example of a cross sectional view taken along line 12C-12C of FIG. 3.

As can be seen in FIG. 12A, gate electrode MG of memory-cell transistor Trm is formed above silicon substrate 2 by way of gate insulating film 3 as described earlier. Gate electrode MG comprises polycrystalline silicon film 4 also referred to as a first/second semiconductor film, interelectrode insulating film 5, polycrystalline silicon film 6 also referred to as a conductive film, and tungsten (W) film 7 also referred to as a metal film are stacked in the listed sequence. Silicon nitride film 8 serving as a hard mask, and silicon oxide film 13 also serving as a hard mask are formed above gate electrode MG in the listed sequence.

Gate electrode MG is spaced from the adjacent gate electrode MG by a first distance. Gate electrode MG located adjacent to select gate electrode SG is also spaced from select gate electrode SG by a first but may alternatively be spaced by a second distance greater than the first distance. In the surface layer of silicon substrate 2 located between gate electrodes MG and between gate electrodes MG and SG, source/drain regions 2a are formed. Silicon oxide film 9 is formed along the upper surface and sidewalls of each gate electrode MG and the upper surface of silicon substrate 2 where source/drain regions 2a are formed. Silicon oxide film 10 and interlayer insulating film 11 comprising a silicon oxide film are stacked in the listed sequence so as to cover silicon oxide film 9. Silicon oxide film 10 is configured to form the air gaps.

Gate electrode SG also comprises polycrystalline silicon film 4a, interelectrode insulating film 5, polycrystalline silicon film 6, and tungsten (W) film 7 stacked in the listed sequence as was the case for gate electrode MG. Silicon nitride film 8, and silicon oxide film 13 are further stacked in the listed sequence above select gate electrode SG. Polycrystalline silicon film 4a of select gate electrode SG has a width, taken along the X direction as viewed in FIG. 3, which is wider than the X-directional widths of interelectrode insulating film 5 and the overlying films. Thus, polycrystalline silicon film 4a of select gate electrode SG protrudes towards the adjacent opposing select gate electrode SG as can be seen, for example, in FIG. 12A. Opening 5a is formed through interelectrode insulating film 5 and polycrystalline silicon film 4a establishes electrical conduction with polycrystalline silicon films 6 through opening 5a. In the surface layer of silicon substrate 2 located between gate electrodes SG, source/drain 2b and highly-concentrated impurity region 2c may be formed to exhibit an LDD (Lightly Doped Drain) structure.

Along the upper surface of gate electrodes SG and the sidewall of gate electrode SG facing the adjacent gate electrode MG, silicon oxide film 9 is formed. Silicon oxide film 9 further extends continuously along the upper surface of silicon substrate 2 located between gate electrodes SG and MG, the sidewall of gate electrode MG facing select gate electrode SG, the upper surface of gate electrode MG, the sidewall of gate electrode MG facing the adjacent gate electrode MG, and along the upper surface of silicon substrate 2 located between gate electrodes MG. Silicon oxide films 10 and 11 extend across the upper surfaces of gate electrodes MG and continuously across the upper surface of select gate electrode SG. Along the sidewall of gate electrode SG opposing the adjacent gate electrode SG, a spacer-shaped silicon oxide film 14 is formed so as to remain over the upper surface of the protruding portion of polycrystalline silicon film 4a. Another spacer-shaped silicon oxide film 15 extends along silicon oxide film 14 and further along the underlying polycrystalline silicon film 4a until reaching the upper surface of silicon substrate 2 so as to oppose the adjacent gate electrode SG.

In FIG. 12B, peripheral circuit transistor Trp is formed in a rectangular element region Saa provided in the surface of silicon substrate 2. Element region Saa is surrounded by element isolation region Sbb. Gate electrode PG is formed so as to extend across the central portion of element region Saa.

Referring to FIG. 12C, gate electrode PG of peripheral circuit transistor Trp is formed above silicon substrate 2 via gate insulating film 3. Peripheral circuit transistor Trp comprises various types of transistors such as a low level voltage transistor and a high level voltage transistor. FIG. 12C illustrates a low level transistor as one example of a peripheral circuit transistor. Some high level voltage transistors are insulated by a thick oxide film instead of a relatively thin gate insulating film 3 employed in memory-cell transistors Trm.

Gate electrode PG also comprises polycrystalline silicon film 9b, interelectrode insulating film 5, polycrystalline silicon film 6, and tungsten (W) film 7 stacked in the listed sequence as was the case for gate electrode SG. Silicon nitride film 8, and silicon oxide film 13 are further stacked in the listed sequence above gate electrode SG. Polycrystalline silicon film 4b is wide in the gate length direction and is protrusive on both gate length directional sides relative to the interelectrode insulating film 5 and the overlying films. Opening 5a is formed through interelectrode insulating film 5 and polycrystalline silicon film 4a establishes electrical conduction with polycrystalline silicon films 6 through opening 5a. In the surface layer of silicon substrate 2 located on both sides of gate electrode PG, source/drain 2d and highly-concentrated impurity region 2e is formed to exhibit an LDD structure.

Along the sidewalls of gate electrode PG, a spacer-shaped silicon oxide film 14 is formed so as to remain over the upper surface of the protruding portions of polycrystalline silicon film 4b. Another spacer-shaped silicon oxide film 15 extends along silicon oxide film 14 and further along the underlying polycrystalline silicon film 4b until reaching the upper surface of silicon substrate 2.

In the above described structure, the sidewalls of tungsten film 7 exposed by etching in the gate patterning of gate electrodes SG and PG are covered by silicon oxide film 14. Thus, contamination originating form the scattering of tungsten etch residues on to the exposed gate insulating film 3 or silicon substrate 2 can be prevented.

Next, a description will be given on one example of a manufacturing process flow of the above described structure with reference to FIGS. 13A to 17B as well. FIG. 13A illustrates structures similar to those of FIG. 5A in that gate structures of gate electrodes MG are isolated prior to the gate structures of select gate electrodes SG and in that air gaps AG have been formed.

Referring to FIG. 13A, gate electrodes MG are formed above the upper surface of silicon substrate 2 via gate insulating film 3. Gate electrode MG comprises polycrystalline silicon film 4 also referred to as a first/second semiconductor film, interelectrode insulating film 5, polycrystalline silicon film 6 also referred to as a conductive film, tungsten (W) film 7 also referred to as a metal film in the listed sequence. Silicon nitride film 8 serving as a hard mask, and silicon oxide film 13 also serving as a hard mask are further formed above gate electrode MG in the listed sequence.

Gate electrode MG is spaced from the adjacent gate electrode MG by a first distance. Gate electrode MG located adjacent to select gate electrode SG is also spaced from select gate electrode SG by the first distance but may alternatively be spaced by a second distance greater than the first distance. Silicon oxide film 9 is formed along the upper surface and sidewalls of each gate electrode MG and the upper surface of silicon substrate 2 in which source/drain regions 2a are formed.

Silicon oxide film 10 and interlayer insulating film 11 comprising a silicon oxide film are stacked in the listed sequence so as to cover silicon oxide film 9. Silicon oxide film 10 is configured to form the air gaps. Silicon oxide film 10 is formed under conditions that provide poor gap fill capabilities. A thin layer of silicon oxide film 10 is lined along the upper surface and sidewalls of gate electrodes MG as well as along the upper surface of silicon substrate 2. Before the gaps between gate electrodes MG and further optionally the gaps between gate electrode MG and the adjacent gate electrode SG are filled, formation of silicon oxide film 10 progresses at the upper portions of the gate structures to form the gaps to thereby form air gaps AG. Silicon oxide film 11 is further formed above silicon oxide film 10.

At this instance, gate patterning has not been carried out in the region corresponding to region K′ of FIG. 3 and in the region corresponding to right side portion of FIG. 5A where select gate electrodes SG are to be formed. Thus, the adjacent select gate electrodes SG are not isolated from each other. Select gate electrode SG comprises a stack of films substantially identical to those of gate electrodes MG. Opening 5a is formed through interelectrode insulating film 5 where the adjacent select gate electrodes SG are to be located, though only the left side opening 5a is shown in FIG. 13A. A recess associated with opening 5a is formed in polycrystalline silicon film 4 and polycrystalline silicon film 6 is filled into the recess. Thus, polycrystalline silicon film 4 establishes electrical conduction with polycrystalline silicon films 6.

FIG. 13B illustrates one phase of the manufacturing process flow corresponding to FIG. 13A. FIG. 13B illustrates one example of a cross sectional view of a portion where gate electrode PG of peripheral circuit transistor Trp is to be formed. As shown, gate insulating film 3, polycrystalline silicon film 4, interelectrode insulating film 5, polycrystalline silicon film 6, tungsten (W) film 7, and silicon nitride film 8 and silicon oxide film 13 serving as a hard mask are stacked in the listed sequence above the upper surface of silicon substrate 2. Opening 5a is formed through interelectrode insulating film, 5 where gate electrodes PG is to be located. A recess associated with opening 5a is formed in polycrystalline silicon film 4 and polycrystalline silicon film 6 is filled into the recess. Thus, polycrystalline silicon film 4 establishes electrical conduction with polycrystalline silicon films 6.

Next, as shown in FIGS. 14A and 14B, resist is formed by photolithography in order to form resist pattern 16 which is used for forming gate electrodes SG and PG. As shown in FIG. 14A, resist pattern 16 covers the region where memory-cell electrodes MG are to be formed as well as the portion where gate electrodes SG are to be formed and has openings in regions where gaps are to be formed between the adjacent select gate electrodes SG. As shown in FIG. 14B, resist pattern 16 further covers the portion where gate electrode PG of peripheral circuit transistor Trp is to be formed and the remaining portions are opened.

Using resist pattern 16 as a mask, anisotropic etching such as RIE is carried out. The etching progresses through silicon oxide films 11, 10, and 13, silicon nitride film 8, tungsten film 7, polycrystalline silicon film 6, and interelectrode insulating film 5 and is temporarily stopped when the upper surface of polycrystalline silicon film 4 is exposed.

Next, as shown in FIGS. 15A and 15B, resist pattern 16 is removed whereafter silicon oxide film 14a is formed in a predetermined thickness. Silicon oxide film 14a extends along the upper surface of silicon oxide film 11 and along the sidewalls of gate electrodes SG and PG formed by the etching. Silicon oxide film 14a is formed between gate electrodes SG formed by the etching and also along polycrystalline silicon film 4 located beside the sidewalls of gate electrode PG also formed by the etching. Silicon oxide film 14a is used to form the spacer-shaped silicon oxide film 14 along the sidewalls of gate electrode SG and PG.

Next, referring to FIGS. 16A and 16B, silicon oxide film 14a is etched back typically by RIE. This removes silicon oxide film 14a formed along silicon oxide film 11 and polycrystalline silicon film 4. As a result silicon oxide film 14 remains in a spacer shape along the sidewalls of gate electrode SG and PG. Thus, the surfaces of tungsten film 7 of gate electrodes SG and PG exposed by the gate patterning is covered by silicon oxide film 14.

Next, as shown in FIGS. 17A and 17B, silicon oxide films 11 and 14 are used as masks to anisotropically etch the exposed polycrystalline silicon film 4 and gate insulating film 3 by RIE to expose the upper surface of silicon substrate 2. Gate insulating film 3 may alternatively remain. Because polycrystalline silicon film 4 is etched with the surfaces of tungsten film 7 covered, it is possible to prevent scattering of tungsten. As a result, the contamination of gate insulating film 3 or silicon substrate 2 caused by attachment of tungsten is prevented. Removal of polycrystalline silicon film 4 in the above described manner completes the gate patterning of gate electrodes SG and PG.

At this instance, polycrystalline silicon film 4a of select gate electrode SG protrudes towards the adjacent select gate electrode SG by a distance substantially equivalent to the width of the spacer-shaped silicon oxide film 14 as can be seen in FIG. 17A. Polycrystalline silicon film 4b is wide in the gate length direction taken along the X direction as viewed in FIG. 3 and is protrusive on both gate length directional sides by a distance substantially equivalent to the width of the spacer-shaped silicon oxide film 14. Then, impurities are introduced into the surface of silicon substrate 2 by ion implantation or the like to form source/drain region 2b and 2d.

Next, silicon oxide film is formed as shown in FIGS. 12A and 12B, which is subsequently etched back to obtain a spacer-shaped silicon oxide film 15 extending along the sidewalls of gate electrodes SG and PG. The exposed surfaces of polycrystalline silicon films 4a and 4b are thus covered. Then, the surface of silicon substrate 2 is heavily doped with impurities by ion implantation or the like to form a highly-concentrated impurity region 2c and 2e exhibiting an LDD structure.

The structures shown in FIGS. 12A and 12B are further subjected to formation of interlayer insulating film, contact plugs, and wiring layers to obtain NAND flash memory device 1.

According to the second embodiment, the surfaces of tungsten film 7 are covered by silicon oxide film 14 when etching polycrystalline silicon film 4 during gate patterning of gate electrodes SG and PG. This prevents the scattering of tungsten etch residues on to silicon substrate 2 or gate insulating film 3 and therefore prevents tungsten contamination.

The second embodiment is based on the first embodiment in which tungsten contamination is addressed in the gate patterning of memory-cell transistor Trm. However, if tungsten contamination need not be addressed for memory-cell transistors Trm, the second embodiment and subsequent embodiments need not be based on the first embodiment.

### Third Embodiment

FIGS. 18A and 18B illustrate a third embodiment. The following description is primarily directed to the differences from the second embodiment. FIG. 18A illustrates one example of a plan view of the third embodiment and corresponds to FIG. 12B of the second embodiment. FIG. 18B is one example of a cross sectional view taken along line 18B-18B of FIG. 18A.

Referring to FIG. 18A, peripheral circuit transistor Trp is formed in a rectangular element region Saa provided in the surface of semiconductor substrate 2. Element region Saa is surrounded by element isolation region Sbb. Gate electrode PG extends across the central portion of element region Saa.

Referring to FIG. 18B, gate electrode PG is similar in structure to gate electrode PG described in the second embodiment in that polycrystalline silicon film 4b is wide in the gate length direction and is protrusive on both gate length directional sides relative to interelectrode insulating film 5 and the overlying films. Above the upper surface of the protruding portions polycrystalline silicon film 4b, silicon oxide film 14 is formed in a spacer-like shape and silicon oxide film 15 is further formed along the outer side of silicon oxide film 14 as was the case in the second embodiment. Interlayer insulating film 16 is further formed above the foregoing structures.

As shown in FIG. 18B, gate contact 17 extends through interlayer insulating film 16 and silicon oxide film 14 to establish contact with the upper surface of the protruding portion of polycrystalline silicon film 4b. Gate contact 17 is connected to a wiring layer not shown provided above interlayer insulating film 16 and thereby establishes electrical contact with polycrystalline silicon film 4b.

The contact hole of gate contact 17 can be formed relatively easily by anisotropically etching downward through silicon oxide film 14 by RIE, or the like. Thus, gate contact 17 can be configured to establish direct contact with polycrystalline silicon film 4b without having to extend through the overlying layers of gate electrode PG such as tungsten film 7 and polycrystalline silicon film 6. In the third embodiment, opening 5b formed through interelectrode insulating film 5 in the second embodiment has been eliminated since gate contact 17 is configured to establish direct contact with polycrystalline silicon film 4b.

It is possible for the gate contact 17 to improve device properties through reduced electrical resistance as compared to a structure in which the gate contact contacts tungsten film 7 through opening of interlayer insulating film 16. Gate electrode PG may employ a barrier metal film comprising tungsten nitride (WN) between tungsten film 7 and polycrystalline silicon film 6 which may increase interfacial resistance. However, the above described gate contact 17 advantageously establishes direct contact with polycrystalline silicon film 4 without having to extend through the overlying films of the gate stack, and thereby improves the properties of the peripheral circuit transistor.

The above described gate contact 17 employed in peripheral circuit transistor Trp is merely an example. Similar gate contact structure may be employed in establishing contact to polycrystalline silicon film 4b employed in a resistor provided in the peripheral circuit. Such configuration suppresses adverse factors such as resistivity variation and operational delay and thereby stabilizes the working of the resistor.

Similar gate contact structure may be applied in a capacitor being configured by silicon substrate 2 and polycrystalline silicon film 4b serving as a conductor, with gate insulating film 3 interposed therebetween. Similar gate structure may also be applied in a capacitor being configured by polycrystalline silicon film 6 and polycrystalline silicon film 4b serving as a conductor, with interelectrode insulating film 5 interposed therebetween.

### Fourth Embodiment

FIGS. 19A to 24B illustrate a fourth embodiment and shows one example of how select gate electrodes SG and PG may be formed after obtaining the structure shown in FIGS. 5A and 5B of the first embodiment. As described in the first embodiment, FIGS. 5A and 5B illustrate the state in which patterning of gate electrodes MG and formation of air gaps AG between gate electrodes MG have been completed. The following description will also refer to the figures of the first embodiment where required.

Gate electrodes MG illustrated in FIG. 19A are similar in structure to those illustrated in FIG. 5A and thus will not be described. Gate electrode SG comprises polycrystalline silicon film 4a, interelectrode insulating film 5, polycrystalline silicon film 6, and tungsten (W) film 7 stacked in the listed sequence as was the case for gate electrode MG. Silicon nitride film 8 is further formed above select gate electrode SG. Polycrystalline silicon film 4a of select gate electrode SG has a width, taken along the X direction as viewed in FIG. 3, which is wider than the X-directional widths of interelectrode insulating film 5 and the overlying films. As shown, polycrystalline silicon film 4a of select gate electrode SG protrudes towards the adjacent select gate electrode SG but not towards the adjacent memory-cell gate electrode MG. Opening 5a is formed through interelectrode insulating film 5 and polycrystalline silicon film 4a establishes electrical conduction with polycrystalline silicon film 6 through opening 5a. In the surface layer of silicon substrate 2 located between gate electrodes SG, source/drain 2b and highly-concentrated impurity region 2c are formed to exhibit an LDD structure.

Along the upper surface of gate electrode SG and the sidewall of gate electrode SG facing the adjacent gate electrode MG, silicon oxide film 9 is formed. Silicon oxide films 10 and 11 extend across the upper surfaces of gate electrodes MG and continuously across the upper surface of select gate electrode SG. Along the sidewall of gate electrode SG opposing the adjacent gate electrode SG, a spacer-shaped silicon oxide film 14 is formed so as to rest over the upper surface of the protruding portion of polycrystalline silicon film 4a. Another spacer-shaped silicon oxide film 15 extends along silicon oxide film 14 and further along the underlying polycrystalline silicon film 4a until reaching the upper surface of silicon substrate 2 so as to oppose the adjacent gate electrode SG.

Referring to FIG. 19B, gate electrode PG is formed above the upper surface of silicon substrate 2 via gate insulating film 3. Peripheral circuit transistor Trp comprises various types of transistors such as a low level voltage transistor and a high level voltage transistor. FIG. 19B illustrates a low level transistor as one example of a peripheral circuit transistor.

Gate electrode PG also comprises polycrystalline silicon film 4b, interelectrode insulating film 5, polycrystalline silicon film 6, and tungsten (W) film 7 stacked in the listed sequence as was the case for gate electrode SG. Silicon nitride film 8 is further formed above gate electrode PG. Polycrystalline silicon film 4b is wide in the gate length direction and is protrusive on both gate length directional sides relative to interelectrode insulating film 5 and the overlying films. Opening 5b is formed through interelectrode insulating film 5 and polycrystalline silicon film 4a establishes electrical conduction with polycrystalline silicon films 6 through opening 5b. In the surface layer of silicon substrate 2 located on both sides of gate electrode PG, source/drain 2d and highly-concentrated impurity region 2e may be formed to exhibit an LDD structure.

Along the sidewalls of gate electrode PG, a spacer-shaped silicon oxide film 14 is formed so as to rest over the upper surface of the protruding portion of polycrystalline silicon film 4b. Another spacer-shaped silicon oxide film 15 extends along silicon oxide film 14 and further along the underlying polycrystalline silicon film 4b until reaching the upper surface of silicon substrate 2.

Next, a description will be given on one example of a manufacturing process flow of the above described structure with reference to FIGS. 20A to 24B as well. FIG. 20A illustrates structures similar to those of FIG. 5A in that gate structures of gate electrodes MG are isolated prior to the gate structures of select gate electrodes SG and in that air gaps AG have been formed. In other words, select gate electrode SG is yet to be patterned.

FIG. 20B illustrates one example of a cross sectional view of a portion where gate electrode PG is to be formed. As shown, gate patterning is yet to be performed. Similar to the structure illustrated in FIG. 20A, gate insulating film 3, polycrystalline silicon film 4, interelectrode insulating film 5, polycrystalline silicon film 6, tungsten (W) film 7, and silicon nitride film 8 serving as a hard mask are stacked in the listed sequence above the upper surface of silicon substrate 2. Opening 5b is formed through interelectrode insulating film 5 where gate electrodes PG is to be located. A recess associated with opening 5b is formed in polycrystalline silicon film 4 and polycrystalline silicon film 6 is filled into the recess. Thus, polycrystalline silicon films 4 establish electrical conduction with polycrystalline silicon film 6.

Next, as shown in FIGS. 21A and 21B, gate electrodes SG and PG are patterned by photolithography and etching. Using a mask pattern made of a resist, anisotropic etching such as RIE is carried out. The etching progresses through silicon oxide films 11 and 10, silicon nitride film 8, tungsten film 7, polycrystalline silicon film 6, and interelectrode insulating film 5 and is temporarily stopped when the upper surface of polycrystalline silicon film 4 is exposed.

Next, as shown in FIGS. 22A and 22B, silicon oxide film 14a is formed in a predetermined thickness. Silicon oxide film 14a extends along the upper surface of silicon oxide film 11 and along the sidewalls of gate electrodes SG and PG formed by the etching. Silicon oxide film 14a is used to form the spacer-shaped silicon oxide film 14 along the sidewalls of gate electrodes SG and PG.

Next, referring to FIGS. 23A and 23B, silicon oxide film 14a is etched back typically by RIE. The silicon oxide film 14a formed above silicon oxide film 11 and polycrystalline silicon film 4 is removed, and silicon oxide film 14 remains in a spacer shape along the sidewalls of gate electrodes SG and PG. Thus, the surfaces of tungsten film 7 of gate electrodes SG and PG exposed by the gate patterning is covered by silicon oxide film 14.

Next, as shown in FIGS. 24A and 24B, silicon oxide films 11 and 14 are used as masks to anisotropically etch the exposed polycrystalline silicon film 4 and gate insulating film 3 by RIE to expose the upper surface of silicon substrate 2. Gate insulating film 3 may alternatively remain. Because polycrystalline silicon film 4 is etched with the surfaces of tungsten film 7 covered with silicon oxide film 14, scattering of tungsten can be prevented to suppress contamination of gate insulating film 3 or silicon substrate 2 caused by attachment of tungsten. Removal of polycrystalline silicon film 4 in the above described manner completes the gate patterning of gate electrodes SG and PG.

At this instance, polycrystalline silicon film 4a of select gate electrode SG protrudes towards the adjacent select gate electrode SG by a distance substantially equivalent to the width of the spacer-shaped silicon oxide film 14 as can be seen in FIG. 24A. Further, as shown in FIG. 24B, polycrystalline silicon film 4b is wide in the gate length direction taken along the X direction as viewed in FIG. 3 and is protrusive on both gate length directional sides by a distance substantially equivalent to the width of the spacer-shaped silicon oxide film 14. Then, impurities are introduced into the surface of silicon substrate 2 by ion implantation or the like to form source/drain region 2b and 2d.

Next, silicon oxide film is formed as shown in FIGS. 19A and 19B, which is subsequently etched back to obtain a spacer-shaped silicon oxide film 15 extending along the sidewalls of gate electrodes SG and PG. The surfaces of polycrystalline silicon films 4a and 4b are thus covered by silicon oxide film 15. Then, the surface of silicon substrate 2 is heavily doped with impurities by ion implantation or the like to form a highly-concentrated impurity region 2c and 2e exhibiting an LDD structure.

The structures shown in FIGS. 19A and 19B are further subjected to formation of interlayer insulating film, contact plugs, and wiring layers to obtain NAND flash memory device 1.

According to the fourth embodiment, the surfaces of tungsten film 7 are covered by silicon oxide film 14 when etching polycrystalline silicon film 4 during gate patterning of gate electrodes SG and PG. This prevents the scattering of tungsten etch residues on to silicon substrate 2 and gate insulating film 3 and therefore prevents tungsten contamination.

Thus, tungsten contamination which is of concern in the gate patterning of memory-cell region and peripheral circuit region can be prevented when control gate electrode CG employs a poly-metal structure in which tungsten film, 7 is stacked above polycrystalline silicon film 6. Thus, tungsten contamination can be prevented not only during gate patterning of gate electrodes MG but also during gate patterning of gate electrodes SG and PG.

### Other Embodiments

The foregoing embodiments may be modified as follows.

The first/second semiconductor film and conductive film comprising polycrystalline silicon film may alternatively comprise amorphous silicon film or semiconductor films other than a silicon film.

Control gate electrode CG comprising a stack of polycrystalline silicon film 6 and tungsten film 7 may employ metal films other than tungsten. Examples of alternative metal films include aluminum (Al), tungsten silicide (WSi), molybdenum (Mo), and tantalum (Ta) or materials based on the foregoing metals. As discussed in the foregoing embodiments, a barrier metal film may be provided above polycrystalline silicon film 6 when forming the metal film. The barrier metal film may comprise any material that suppresses reaction between the metal film and the polycrystalline silicon film. Examples of such material include tungsten nitride (WN), tungsten silicon nitride (WSiN), titanium nitride (TiN), ruthenium (Ru), ruthenium oxide (RuO), tantalum (Ta), tantalum nitride (TaN), tantalum silicon nitride (TaSiN), manganese (Mn), manganese oxide (MnO), niobium (Nb), niobium nitride (NbN), molybdenum nitride (MoN), and vanadium (Vn).

Accordingly, the combination of metal film and barrier metal film exemplified as tungsten film and tungsten nitride film in the foregoing embodiments may be replaced by various combinations of materials raised above.

Silicon oxide film 12 formed by plasma was given as an example of a film providing poor step coverage. Other type of insulating films may be employed so long as such film is capable of covering the exposed surfaces of tungsten film 7 during gate patterning.

Gate patterning of gate electrode MG was performed prior to gate electrodes SG and PG in the first embodiment. Alternatively, gate patterning of gate electrodes MG, SG, and PG may be performed at the same time in case tungsten contamination of gate electrodes SG and PG is not a problem.

The foregoing embodiments were applied to structures having air gaps AG between gate electrodes MG, however, the embodiments are also generally applicable to structures employing poly-metal control gate electrodes CG/word lines WL.

The foregoing embodiments were described through NAND flash memory device 1, but may alternatively be applied to other nonvolatile semiconductor storage devices such as a NOR flash memory device or EEPRROM. Embodiments directed to a single bit memory cell MT and multi-bit memory cell MT both fall within the scope of the application.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a semiconductor substrate;
a plurality of memory-cell transistors located in a memory-cell region, each of the memory-cell transistors including a gate insulating film formed on the semiconductor substrate and a memory-cell gate electrode including a first semiconductor film, an insulating film, and a conductive film;
a plurality of word lines each interconnecting the conductive film of the memory-cell transistors aligned in a first direction and each including a hook-up portion located in a hook-up region located outside the memory-cell region; and
an interlayer insulating film disposed on the upper surface of the memory-cell gate electrodes so as to form a gap between the memory-cell gate electrodes;
wherein a second semiconductor film and a first insulating film are disposed in the hook-up region, the second semiconductor film and the first semiconductor film being made of the same material, and the insulating film and the first insulating film being made of the same material, and
wherein the interlayer insulating film covers an upper surface of the first insulating film and an upper surface of the plurality of word lines in the hook-up portion.

2. The device according to claim 1, further comprising a plurality of select gate electrodes,
wherein a first number of memory-cell gate electrodes aligned in a second direction intersecting with the first direction constitute a group and one of the select gate electrodes is disposed beside the group in the second direction, and wherein a distance between adjacent memory-cell gate electrodes and between adjacent memory-cell gate electrode and select gate electrode are a first distance in the second direction.

3. The device according to claim 1, wherein the hook-up region includes a second insulating film located between the semiconductor substrate and the second semiconductor film, and a thickness of the second insulating film is equal to a thickness of the gate insulating film.

4. The device according to claim 1, wherein each of the memory-cell gate electrodes further includes a metal film above the conductive film, the metal film of the memory-cell gate electrodes being interconnected by each word line.

5. The device according to claim 1, wherein an end portion of the gap extending in the first direction is located in the hook-up region, and an edge portion of the second semiconductor film located in the hook-up region forms a curved surface.

6. The device according to claim 1, wherein an end portion of the gap extending in the first direction is located in the hook-up region, and the interlayer insulating film located at the end portion only contacts a silicon oxide film located above the first insulating film.

7. The device according to claim 1, wherein the hook-up portion of each word line includes a pad portion, and wherein the second semiconductor film is located between the pad portions.

8. A nonvolatile semiconductor storage device comprising:
a semiconductor substrate;
a plurality of memory-cell transistors located in a memory cell region, each of the memory-cell transistors including a first gate insulating film formed on the semiconductor substrate and a memory-cell gate electrode including a first semiconductor film, a first insulating film, and a first metal film, wherein a first number of memory-cell gate electrodes constitute a group;
a plurality of select transistors, each of the select transistors including a second gate insulating film formed on the semiconductor substrate and a select gate electrode including a second semiconductor film, a second insulating film, and a second metal film, wherein one of the select gate electrodes is disposed beside the group;
a plurality of peripheral circuit transistors located in a peripheral circuit region, each of the peripheral circuit transistors including a third gate insulating film formed on the semiconductor substrate and a peripheral-circuit gate electrode including a third semiconductor film, a third insulating film, and a third metal film;
wherein the select gate electrode includes a first side surface facing each of plurality of select transistors and including a first protrusion comprising the second semiconductor film and a first sidewall disposed on the first protrusion and includes a first spacer comprising an insulating film disposed on the first protrusion and extending along the first sidewall,
wherein the peripheral circuit gate electrode includes a second side surface including a second protrusion comprising the third semiconductor film and a second sidewall disposed on the second protrusion and includes a second spacer comprising an insulating film disposed on the second protrusion and extending along the second sidewall.

9. The device according to claim 8, wherein the memory-cell gate electrodes are spaced from one another by a first distance, the select gate electrodes are spaced from one another by a second distance greater than the first distance, and the peripheral circuit gate electrodes are spaced from one another by a third distance greater than the first distance.

10. The device according to claim 8, further comprising a gate contact penetrating through the second spacer from the upper surface thereof to contact the third semiconductor film.

11. A method of manufacturing a nonvolatile semiconductor storage device, comprising:
forming a gate insulating film, a first semiconductor film serving as a floating gate electrode, an insulating film, and a metal film on a semiconductor substrate;
etching the metal film while leaving the first semiconductor film to form word lines;
forming a cover insulating film so as to at least cover surfaces of the metal film exposed by the etching;
etching the first semiconductor film using the cover insulating film as a mask to form a plurality of memory-cell gate electrodes for memory-cell transistors; and
forming an interlayer insulating film across upper surfaces of the memory-cell gate electrodes.

12. The method according to claim 11, wherein forming the cover insulating film includes forming a silicon oxide film using plasma under conditions providing poor step coverage to form gaps between the memory-cell gate electrodes.

13. The method according to claim 11, wherein forming the interlayer insulating film includes forming a silicon oxide film using plasma under conditions providing poor step coverage.

14. The method according to claim 11, wherein forming the cover insulating film includes forming a silicon oxide film using plasma under conditions providing poor step coverage to form gaps between the memory-cell gate electrodes, and wherein the cover insulating film fills spaces between the word lines in a pad portion.
